(19) United States
(12) Patent Application Publication
(10) Pub. No.: US 2018/0025877 A1
(43) Pub. Date: Jan. 25, 2018

(54) DEVICE AND METHOD FOR MONITORING AN INTERRUPTION UNIT IN AN ELECTRICAL POWER SUPPLY NETWORK, AND A DISTRIBUTION STATION WITH A MONITORED INTERRUPTION UNIT

(71) Applicant: SIEMENS AKTIENGESELLSCHAFT, Muenchen (DE)

(72) Inventors: Wiebke FROEHNER, Amberg (DE); Thomas WERNER, Rednitzhembach (DE)

(21) Appl. No.: 15/656,468

(22) Filed: Jul. 21, 2017

(30) Foreign Application Priority Data
Jul. 22, 2016 (EP) 16180761.5

(51) Int. Cl. H01H 71/04; G01R 31/327; H01H 85/30

(52) U.S. Cl. CPC H01H 71/04; H01H 85/30; G01R 31/3277; H02H 7/26

(57) ABSTRACT

A device for monitoring an interruption unit in an electrical energy supply network. In order to reduce the cost incurred by a network operator in detecting and localizing tripped interruption units, the device has a sensor interface for connecting a sensor unit that records a measured value specific to the interruption unit. An evaluation unit is connected to the sensor interface and configured to detect a current change in terms of the current flowing through the interruption unit on the basis of the measured value. A communication interface is connected to the evaluation unit. In the event of a detected current change, a status signal indicating a critical status of the interruption unit is transmittable to a communication unit. We also describe a method for monitoring an interruption device, and a distribution station with a device for monitoring an interruption device.

### CROSS-REFERENCE TO RELATED APPLICATION

This application claims the priority, under 35 U.S.C. §119, of European patent application EP 16180761, filed Jul. 22, 2016; the prior application is herewith incorporated by reference in its entirety.

### BACKGROUND OF THE INVENTION

### Field of the Invention

The invention relates to a device and a method for monitoring an interruption unit in an electrical power supply network. The invention also relates to a distribution station with a monitored interruption unit.

Distribution stations, such as, for instance, substations or cable distribution stations, are used in many public medium-voltage and low-voltage networks. Substations serve to connect the medium-voltage network to cable distribution cabinets in the low-voltage network; cable distribution cabinets are provided to connect the network connections of the individual end consumers (households, offices, trade, small industry) to an associated substation. Here, a cable first leads from the substation to the cable distribution cabinet. One or more busbars are located there, to which the individual line branches which lead to the respective network connections are connected.

The busbars and/or the individual branches in distribution stations of this type are normally protected with NH fuses (NH fuse=low-voltage, high-power fuse) or electromechanically tripped switching devices to protect the branch against thermal overload or short circuits. The NH fuses are often blow-out fuses. Fuses (including NH fuses) and electromechanically tripped switching devices are also referred to below as “interruption units.”

Today, these interruption units in distribution stations are not generally remotely monitored. As a result of the lack of remote monitoring, the process of fault detection and fault location in the medium-voltage and low-voltage network is time-consuming and labor-intensive.

The network operator of a low-voltage network, for example, is in fact initially reliant on its customers to inform it, for example by telephone, of a power failure. However, the cause of the power failure may be located here both in the public network and in the customer's equipment. The network operator must therefore initially wait for information from the customer in order to obtain assurance that the cause of the power failure is actually located in its network. Using the address information of the customers, it can then identify the network segment in which the fault is presumably located. The network operator then notifies a maintenance team which must locate the tripped interruption unit. The maintenance team inspects the cable distribution cabinets concerned and visually checks whether one of the fuses installed in the cable distribution cabinet has tripped. A visual indicator of the fuse is used for this purpose.

A visual status indicator for NH fuses is described, for example, in U.S. patent application publication US 2013/0002393 A1 (WO 2011/114176 A1). A fuse rail for NH fuses which is to be installed in a cable distribution cabinet is known from European published patent application EP 1 271 583 A2. Finally, European published patent application EP 0 068 490 A2 shows a cable distribution cabinet with NH fuses which has a particularly space-saving design. A substation in a medium-voltage network is furthermore known, for example, from international publication WO 2014/201475 A1.

### SUMMARY OF THE INVENTION

It is accordingly an object of the invention to provide a monitoring system which overcomes the above-mentioned and other disadvantages of the heretofore-known devices and methods of this general type and which reduces the cost incurred by a network operator in detecting and locating tripped interruption units.

With the foregoing and other objects in view there is provided, in accordance with the invention, a device for monitoring an interruption unit in an electrical energy supply network, the device comprising:

a sensor interface for connecting a sensor unit for acquiring a measured value specific to the interruption unit;

an evaluation unit connected to said sensor interface, said evaluation unit being configured to detect a current change in terms of a current flowing through the interruption unit on a basis of the measured value; and

a communication interface connected to said evaluation unit and configured to transmit, in the event of a detected current change, a status signal indicating a critical status of the interruption unit to a communication unit.

In other words, the objects of the invention are achieved by a device for monitoring an interruption unit in an electrical energy supply network which has a sensor interface for the connection of a sensor unit for recording a measured value specific to the interruption unit, an evaluation unit which is connected to the sensor interface and which is configured to detect a current change in terms of the current flowing through the interruption unit on the basis of the measured value, and a communication interface which is connected to the evaluation unit and via which, in the event of a detected current change, a status signal indicating a critical status of the interruption unit can be output to a communication unit.

The invention is based on the realization that interruption units, e.g. blow-out fuses, are essentially tripped for two reasons: in the case of long-lasting currents resulting in thermal overload of the lines, or in the case of short circuits. Both events are accompanied by quickly and significantly changing currents flowing through the interruption units. Here, a sudden change, as in the event of a short circuit, either results in the tripping of the interruption unit, or it results from the tripping of the interruption unit itself, since a sudden current change occurs due to the current interruption. In order to monitor an interruption unit, it is therefore necessary to detect a sudden current change of this type and identify an (imminently tripping or already tripped) interruption unit therefrom. In order to detect a current change which indicates a tripping of the interruption unit, the measured value can be compared, for example, with one or more threshold values, or specific patterns in the changing measured value can be evaluated and identified.

One particular advantage of the invention is that a remote monitoring of interruption units is enabled with the device according to the invention. Tripped interruption units can thus be identified immediately and the cost of the fault location can be significantly reduced. Along with the cost benefits (e.g. due to a shorter deployment time of the maintenance teams), a reduction in the downtime of the power supply is therefore also achieved. In regulated power networks, the downtime (known as the “SAIDI Index”) is often used as a quality criterion on the basis of which the network operator is penalized or rewarded accordingly, so that the remote monitoring offers a further economic benefit for the network operator.

The sensor unit and the communication unit may form separate units and may be connected via the respective interfaces to the evaluation unit. In this case, the sensor unit may be designed as a probe which is installed at a suitable location in the distribution station in order to record the measured value.

In particular, a status following the tripping of the interruption unit is regarded here as a critical status of the interruption unit (e.g. in the case of a blow-out fuse following the melting of the fuse element) in which the interruption unit permanently interrupts the current flow.

According to one advantageous embodiment of the device according to the invention, it is provided that a sensor unit for recording the measured value is connected to the sensor interface, and the evaluation unit and the sensor unit are disposed in a common housing.

According to this advantageous embodiment, the sensor unit is integrated into the device. In this case, the sensor interface represents an internal interface which connects the sensor unit to the evaluation unit.

In this connection, it can be specifically provided that the sensor unit comprises a Hall sensor. A Hall sensor serves to record a magnetic field and is known as such to the person skilled in the art. A Hall sensor emits a voltage signal on the basis of which the strength of the magnetic field can be inferred. Since a current flowing through a conductor generates a magnetic field detectable with the Hall sensor, a change in the magnetic field can be identified by evaluating the output signal of the Hall sensor. Finally, a change in the magnetic field signifies a change in the current flow through the interruption unit, so that a change in the current through the interruption unit can be identified on the basis of the measured value recorded by means of the Hall sensor. This specific embodiment is therefore based on the realization that a sudden current change can be detected on the basis of a measurement of the magnetic field.

A further advantage of the use of a Hall sensor is the compact structure of said sensor. Particularly in cable distribution cabinets, but to some extent in substations also, only limited space is normally available for further installations, so that attention must be given to a small structure of the device for monitoring the interruption units.

A further advantage of the monitoring of the magnetic field is that it is sufficient to monitor the change in the entire magnetic field within the distribution station for the basic identification of the distribution station in which an interruption unit has tripped. A monitoring relating to the individual branch is not necessary, since the maintenance team, after identifying the distribution station concerned, can very easily identify the tripped interruption unit through visual inspection.

However, according to a different advantageous embodiment, it can also be provided that the sensor unit comprises a current sensor.

Both a conventional inductive transformer (e.g. a toroidal transformer) and an unconventional transformer (e.g. Rogowski coil) can be considered as a current sensor. The specific selection of the sensor is ultimately dependent on the available space in the distribution station and on the costs for the procurement and installation of the sensors.

In a further advantageous embodiment of the device according to the invention, a communication unit is connected to the communication interface and the evaluation unit and the communication unit are disposed in a common housing.

According to this advantageous embodiment, the communication unit is integrated into the device. In this case, the communication interface represents an internal interface which connects the communication unit to the evaluation unit.

It can be provided specifically in this connection that the communication unit is a radio module.

This embodiment offers the advantage that no dedicated communication lines need to be connected to the cable distribution cabinet. A radio module may, for example, be a GSM module, a GPRS module, a UMTS module, a LoRaWAN (Low Range Wide Area Network) module, a narrowband IoT (Internet of Things) module or the like.

In this connection, it is furthermore regarded as advantageous if the device has a connection for connecting to a radio antenna.

The radio antenna may be mounted here externally on the distribution station. However, in the case of a distribution station material which is correspondingly permeable to radio waves (e.g. a cable distribution cabinet made from glass-fiber-reinforced polyester), an internal antenna can also be used. This can also be integrated into the device.

If the distribution station is already equipped with a cable-connected communication connection (e.g. an Ethernet IP connection), this can obviously also be used to transmit the status signal.

An external power supply which is fed through the current-carrying lines of the distribution station itself or through electrical auxiliary power for installations can be provided for the power supply of the device. It is furthermore also conceivable for the device to be provided with a battery, thereby totally eliminating the need for an external power supply.

A further advantageous embodiment of the invention provides that the device is provided with a machine-readable code which indicates a unique identification of the device.

A simplified procedure for installing the device in a higher-order monitoring system can thereby be supported. The machine-readable code may, for example, be a barcode, a QR (QR=Quick Response) code or a sequence of alphanumeric characters (e.g. a serial number). This code can be read and evaluated by means of a suitable reading device (e.g. scanner, Smartphone, etc.) during the installation of the device in the distribution station. The identification information of the device can then be transmitted to a higher-order monitoring system in order to allocate the device to the specific distribution station. To do this, location data can additionally be recorded which indicate the geographical location (geocoordinates) and/or the topological location (node point in the power network) at which the distribution station is set up, in order to make it easier for the maintenance team to locate the failed interruption unit.

The identification information and, where relevant, the location information are transmitted to the higher-order monitoring system and are stored there.

With the above and other objects in view there is also provided, in accordance with the invention, a method for monitoring an interruption unit in an electrical energy supply network with a device as outline above. The method comprises:

acquiring a measured value specific to the interruption unit with a sensor unit associated with the device;

examining the measured value with the evaluation unit of the device for the occurrence of a current change in a current flowing through the interruption unit; and

if a current change is detected, outputting a status signal indicating a critical status of the interruption unit by way of a communication unit of the device.

In other words, the above objects are achieved by a method for monitoring an interruption unit in an electrical power supply network with a device as described above. According to the invention, a measured value specific to the interruption unit is recorded in the method with a sensor unit allocated to the device, the measured value is examined with an evaluation unit of the device for the occurrence of a current change in the current flowing through the interruption unit and, if a current change occurs, a status signal indicating a critical status of the interruption unit is output by means of a communication unit allocated to the device.

A remote monitoring of an interruption unit of a power supply network can be carried out particularly advantageously in this way.

With regard to the method according to the invention, all details described above and below for the device according to the invention and vice versa apply accordingly, in particular the device according to the invention is configured to carry out the method according to the invention in any given embodiment or a combination of any given embodiments. Also with regard to the advantages of the method according to the invention, reference is made to the advantages described for the device according to the invention and vice versa.

According to one advantageous embodiment of the method according to the invention, it can be provided that the device is installed in a distribution station (e.g. a cable distribution cabinet or a substation) before commissioning.

As a result, the interruption units can be particularly effectively monitored in the immediate vicinity of their installation location. With a suitable design of the device, in particular with the use of a Hall sensor to measure the magnetic field in the vicinity of the interruption units, a single device is furthermore sufficient for monitoring all interruption units present in the distribution station, since one measurement of the entire magnetic field in the distribution station can be carried out here instead of having to carry out one or more measurements for each branch.

According to one advantageous embodiment, it can be provided in this connection that a machine-readable code containing identification information enabling a unique identification of the device is recorded during the installation.

The recording of the device in a higher-order monitoring system, e.g. a network control system or a cloud service, can be simplified as a result. In this case, the technician installing the device in the distribution station can read in the code by simply reading in the machine-readable code (barcode, QR code, etc.), for example by means of a camera of a Smartphone or with a dedicated scanner, and can determine the identification information therefrom. The latter can then be sent to the higher-order monitoring system in order to register the device. In this way, manual configuration actions are largely superfluous.

In this connection, it is furthermore regarded as advantageous if the location information indicating the geographical and/or topological location of the distribution station is allocated to the identification information.

The registration of the device in a higher-order monitoring system can be further simplified in this way, since the geographical and/or topological installation location of the device is recorded in addition to its identification. The location information can be recorded, for example, by means of a GPS receiver (e.g. integrated into the Smartphone which is used to read in the code) or by reading in a code affixed to the distribution station and containing the location information. The location information can also be input manually by the technician.

With the above and other objects in view there is also provided, in accordance with a further aspect of the invention, a distribution station in an electrical energy supply network which includes a monitored interruption unit and a device, as described herein, for monitoring the interruption unit.

In terms of the distribution station according to the invention, all details described above and below for the device according to the invention and vice versa apply accordingly. Also with regard to the advantages of the distribution station according to the invention, reference is made to the advantages described for the device according to the invention and vice versa.

According to one advantageous embodiment of the distribution station according to the invention, it can be provided that a plurality of interruption units and a single device for monitoring the plurality of interruption units are disposed in the distribution station.

With a suitable design of the device, in particular with the use of a Hall sensor to measure the magnetic field in the vicinity of the interruption units, it is in fact possible to monitor all interruption units present in the distribution station with a single device, since one measurement of the entire magnetic field in the distribution station can be carried out here instead of having to carry out one or more measurements for each branch.

According to a further advantageous embodiment of the distribution station according to the invention, it can finally be provided that the interruption unit is a blow-out fuse or an electromechanically tripping switch.

Other features which are considered as characteristic for the invention are set forth in the appended claims.

Although the invention is illustrated and described herein as embodied in a device and method for monitoring an interruption unit in an electrical power supply network, and also a distribution station with a monitored interruption unit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a schematic view of a cable distribution cabinet in an electrical low-voltage network;

FIG. 2 is a schematic view of a first exemplary embodiment of a device for monitoring an interruption unit;

FIG. 3 is a schematic view of a second exemplary embodiment of a device for monitoring an interruption unit; and

FIG. 4 shows a process flow diagram to explain the registration of a device for monitoring an interruption unit in a higher-order monitoring system.

### DETAILED DESCRIPTION OF THE INVENTION

The explanations below relate merely by way of example to a device for monitoring an interruption unit in a distribution station in the form of a cable distribution cabinet in a low-voltage network. However, the explanations can also be transferred accordingly to a substation in a medium-voltage network.

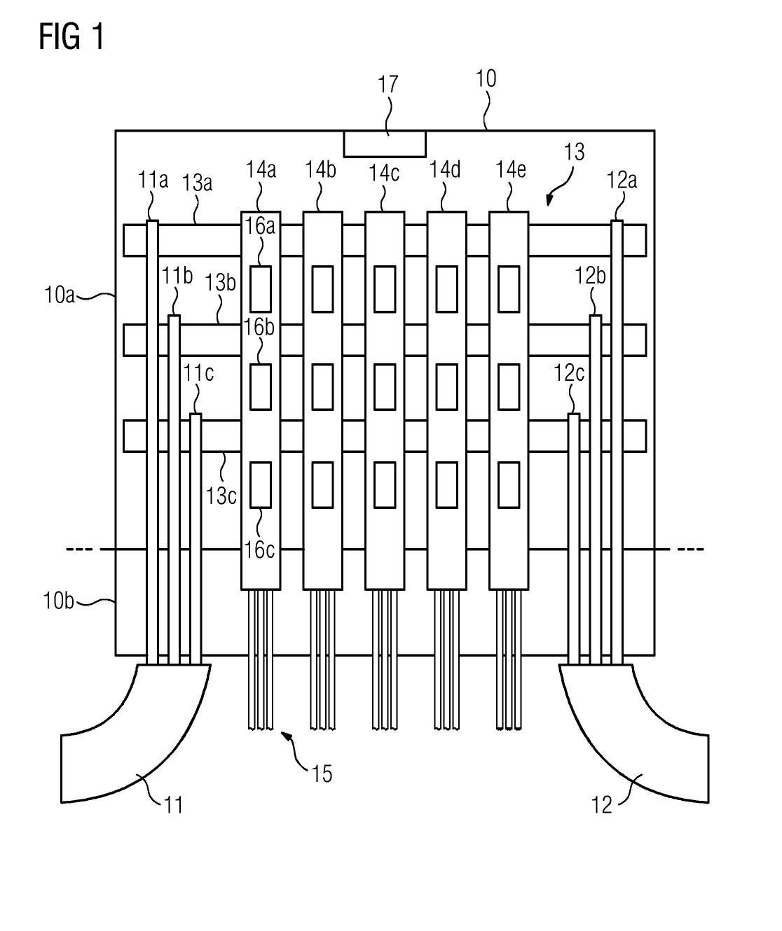

Referring now to the figures of the drawing in detail and first, particularly, to FIG. 1 thereof, there is shown a distribution station 10 in the form of a cable distribution cabinet of an electrical low-voltage network. The cable distribution cabinet has a cabinet part 10a disposed aboveground and a base part 10b embedded in the ground. A first three-phase underground cable 11 is fed into the cable distribution cabinet from below. The individual phases 11a, 11b, 11c of the underground cable 11 are connected in the cable distribution cabinet to different conductors 13a, 13b, 13c of a busbar 13. The first underground cable 11 serves, for example, to electrically connect a substation (not shown in FIG. 1) to the cable distribution cabinet.

A second three-phase underground cable 12 is connected with its individual phases 12a, 12b, 12c to the respective conductors 13a, 13b, 13c of the busbar 13 and is used for the electrical connection of the cable distribution cabinet to a further cable distribution cabinet (not shown in FIG. 1).

Branches 14a, 14b, 14c, 14d and 14e are connected to the individual conductors 13a, 13b, 13c of the busbar 13. These branches serve to connect the cable distribution cabinet electrically to end consumers (e.g., households, trade, offices, small industry). To do this, the individual conductors 13a, 13b, 13c of the busbar 13 are routed on branch lines 15 (identified by way of example for the branch 14a only). The branch lines 15 lead to end consumers located in the vicinity of the cable distribution cabinet.

In order to protect the branch lines 15 against thermal overload due to short circuits or long-lasting high currents, the branches 14a-e are provided with interruption units 16a, 16b, 16c (identified by way of example for the branch 14a only) which may involve, for example, NH blow-out fuses. These interruption units 16a, 16b, 16c permanently interrupt the current flow through the branches in the event of an overload. They must be exchanged by a maintenance team in order to restore the power supply.

To do this, it is necessary for the maintenance team to locate the tripped interruption unit 16a, 16b, 16c as quickly as possible. The tripped interruption unit can be identified comparatively quickly within the cable distribution cabinet through visual inspection. The determination as to which cable distribution cabinet is concerned requires considerably more effort.

A device 17 for monitoring one (or more) interruption unit(s) is used in order to enable a remote monitoring of the interruption units 16a, 16b, 16c and thus simplify the detection of the cable distribution cabinet concerned.

To do this, the device 17 performs the evaluation of a measured value specific to the interruption unit in order to be able to identify any abrupt change in the current flow through the branch (and therefore through the interruption unit) on the basis of the measured value.

If an abrupt current change of this type is detected, it can be assumed that the interruption unit will soon trip or has already tripped in order to interrupt the current flow to protect the branch. On detecting an abrupt current change, the device 17 therefore transmits a status signal to a higher-order monitoring system (not shown in FIG. 1) in order to alert the network operator of the low-voltage network to the overload situation.

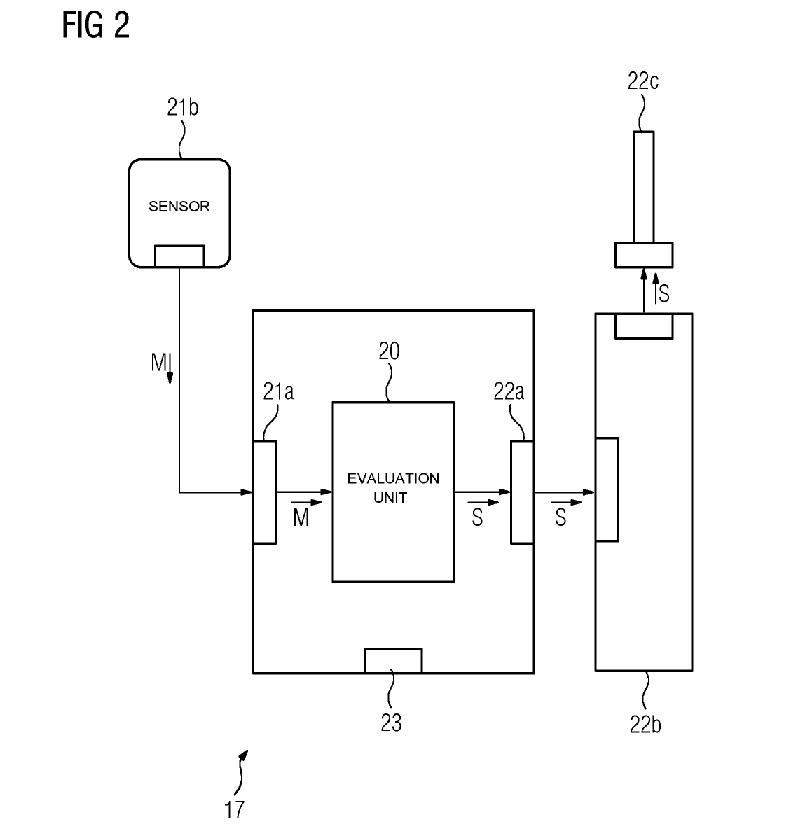

A first exemplary embodiment of a device 17 is shown by way of example in FIG. 2.

The device shown in FIG. 2 has an evaluation unit 20 which is configured to examine a measured value M specific to the interruption unit in order to be able to infer therefrom an abrupt change in the current flowing through the interruption unit. The measured value M may, for example, directly indicate the current through the interruption unit. However, it may also be a measured value indirectly dependent on the current flow, e.g. a magnetic field strength.

In order to acquire the measured value M, the evaluation unit 20 is connected via a sensor interface 21a to a sensor unit 21b which may be, for instance, a Hall sensor. A magnetic field strength can be measured with a Hall sensor. A jump in the current flow through an interruption unit is associated with an abrupt change in the magnetic field due to the interrelationship between the electric and magnetic field. The change is detectable by the evaluation unit 20 through the evaluation of the measured value M that is recorded with the Hall sensor.

In order to be able to inform the network operator in the event of a detected abrupt current change, the evaluation unit 20 is connected via a communication interface 22a to a communication unit 22b (for example a mobile radio module). In the event of a detected abrupt current change, the evaluation unit 20 transmits a status signal S via the communication interface 22a to the communication unit 22b.

The status signal can be transmitted as a radio signal to the higher-order monitoring system via a mobile radio antenna 22c connected to the communication unit 22b.

The power supply of the device 17 is implemented in the example shown in FIG. 2 via the current connection 23 from an external power supply unit which is fed e.g. from an auxiliary circuit of the cable distribution cabinet 10.

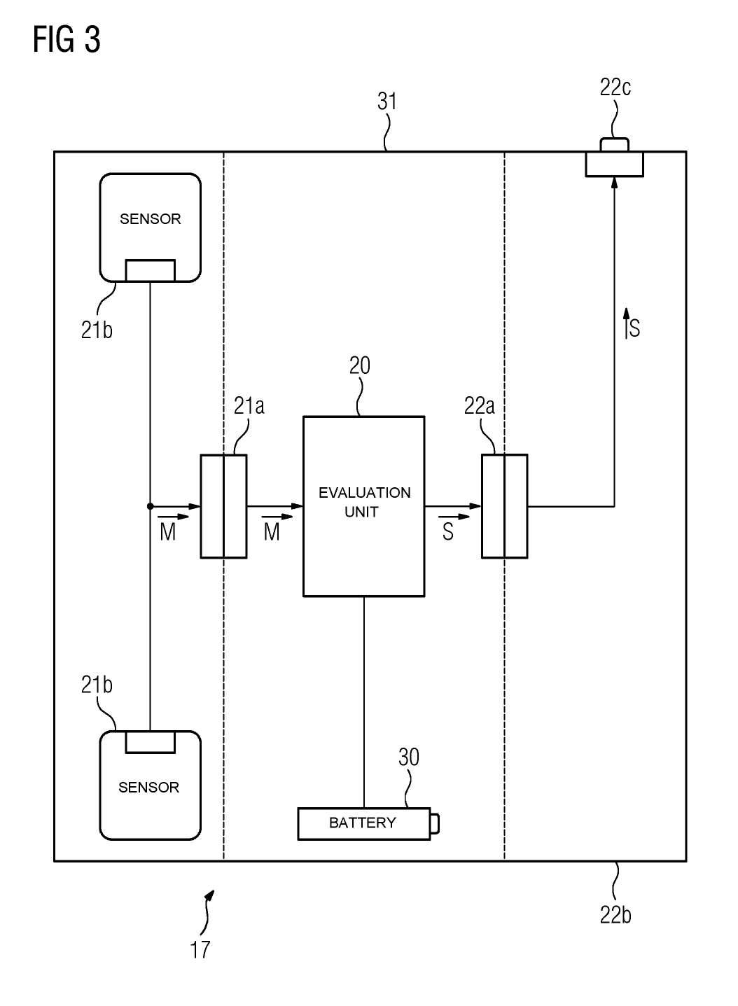

FIG. 3 shows a second exemplary embodiment of a device 17 for monitoring interruption units. Elements in FIGS. 2 and 3 which correspond to one another are indicated with the same reference numbers.

Thus, the device 17 according to FIG. 3 also has an evaluation unit 20 which is connected via a sensor interface 21a to a sensor unit 21b and via a communication interface 22a to a communication unit 22b (with a mobile radio antenna 22c). The mode of operation of the device 17 according to FIG. 3 corresponds to that according to FIG. 2, so that a mere repetition is forgone at this point.

Whereas the device 17 according to FIG. 2 is a device of modular design in which the evaluation unit 20, the sensor unit 21b and the communication unit 22b are disposed on separate modules, the device 17 according to FIG. 3 represents an integrated device in which the evaluation unit 20, the sensor unit 21b and the communication unit 22b are disposed in a common housing 31 (and, if necessary, on a common module).

The device 17 according to FIG. 3 furthermore has an integrated mobile radio antenna 22c.

In contrast to the device 17 according to FIG. 2, the power supply of the device 17 according to FIG. 3 is implemented via a battery 30 inserted into the device 17.

Apart from the embodiments shown in FIGS. 2 and 3, a hybrid design is also conceivable in which, for example, the communication unit 22b is disposed with the evaluation unit 20 in a common housing as in FIG. 3, whereas the sensor unit 21b is designed as a separate probe as in FIG. 2.

As already explained, the device 17 is designed to detect a sudden current change which normally results in a tripping of the corresponding interruption unit or is caused by a tripping of the interruption unit.

In principle, technical approaches can be selected for this purpose, such as, for example, those also used in fault current indicators for overhead lines in medium-voltage networks. Inductive current transformers with an annular structure are mounted around the line and are connected to the evaluation device. This structure is only conditionally suitable for use, particularly in low-voltage cable distribution cabinets, for the following reasons:

The amount of room in existing cable distribution cabinets is frequently very limited, so that the space for use of separate devices for recording and communication and also for the sensors is insufficient. Combinations of this type with comparatively large inductive current transformers can therefore be used only if the existing cable distribution cabinet is exchanged. Inductive current transformers of this type can in principle be used more readily in substations normally having more available space.

Network operators furthermore have a large number of distribution stations. Even smaller network operators may require several thousand distribution stations. The costs for the installation and commissioning of a monitoring device are therefore also significant in terms of economic efficiency.

It is therefore regarded as particularly advantageous if Hall sensors are used instead of conventional current sensors to detect the changes in the magnetic field. The change in the magnetic field of an individual branch does not need to be monitored, but instead the changes in the magnetic fields of all existing branches within the distribution station are monitored, said changes contributing to a change in the overall magnetic field in the distribution station.

The Hall sensors are either housed in a probe (FIG. 2) or are integrated directly into the device (FIG. 3).

For the present application, it is in fact totally sufficient to know the distribution station in which an interruption unit has tripped. It is not necessary to identify the single branch individually.

For this purpose, the device 17 has the evaluation unit 20 which serves to analyze changes in the magnetic field on the basis of the measured value M recorded by means of the sensor unit 21b in the form of a magnetic field strength and to recognize whether these changes have been caused by current changes which have led to the operation of an interruption unit or have resulted from this operation.

For this purpose, the evaluation unit 20 measures the magnetic field inside the distribution station 10 in very short time cycles using the sensor unit 21b and checks whether the changes in the output voltage of the Hall sensors over time match those which indicate a tripping of the interruption unit.

Electronic filters, for example, which evaluate the frequency spectrum of the output signal, or artificial neural networks which search for patterns in sampled voltage values of the Hall sensors can be used for the detection.

The device 17 interacts with a communication module 22b which, in the event of a detected tripping of the interruption unit, transmits a status signal to a higher-order monitoring system, for example to a network control system or a cloud platform.

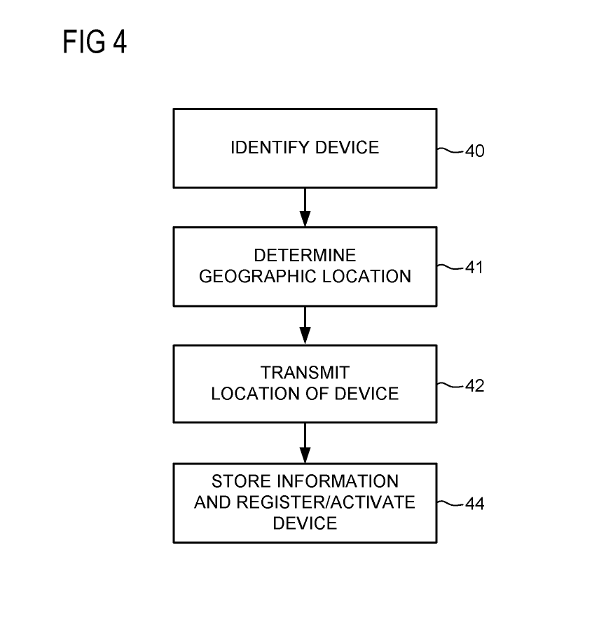

The device can advantageously be designed as a plug-and-play device. This is explained in detail with reference to FIG. 4. For this purpose, a machine-readable code, for example a QR code, is affixed (e.g. imprinted) on the device 17. The code being read in by the technician during the commissioning, e.g., via a Smartphone, as identification information uniquely identifying the device (e.g., a serial number) (step 40).

Using e.g. the location identification of the Smartphone (e.g. via GPS location), the current geographical position of the device 17 or the distribution station is identified (step 41) and is recorded as location information. Alternatively or additionally, the topological position of the device 17 can also be identified.

The location information is transmitted together with the identification information to a higher-order monitoring system (step 42).

The identification information and the location information are stored in the higher-order monitoring system and the device is registered with its identification information and the location information in the system and is activated (step 44).

If the identification information is attached to a status signal of the device 17 during the transmission to the higher-order monitoring system, status signals of the device 17 can be uniquely allocated to the distribution station concerned following the registration and activation. In addition, the geographical and/or topological position of the device or the distribution station can be indicated. A representation in a map service is thus easily possible. A data modeling of the medium-voltage or low-voltage network is not necessary.

The following advantages can be achieved by the use of the device 17:

The device 17 allows a direct detection and location of a tripped interruption unit. It is no longer necessary to wait for the calls from network customers (detection) and to inspect the distribution stations (localization). Penalties and service costs can thus be reduced.

The device 17 can be designed as very small and can therefore be very simply installed in already existing distribution stations, in particular cable distribution cabinets with limited available space. The network operator is therefore not compelled to modify the distribution station. No high modification costs are incurred for converting or dismantling the old distribution station and installing the new distribution station.

The device can be installed without risk during live operation. The supply to the customers connected to the distribution station does not have to be interrupted.

The device requires only two external connections, i.e. one connection for the power supply and one connection for the external antenna of the mobile radio unit. This reduces the design complexity and therefore the device costs. In distribution stations which are manufactured from material permeable to radio waves, e.g. cable distribution cabinets made from glass-fiber-reinforced polyester, the radio antenna can be integrated, if necessary, into the device so that an external antenna is no longer required. Along with the simpler design, vulnerability to vandalism can therefore also be reduced.

The device can be designed so that the evaluation unit can operate a very low current consumption. This eliminates the need for an external power supply and allows the device to be battery-powered. The installation time for the device is thus further reduced.

The design without external sensors offers a further cost benefit (no external sensors, no cabling and connections).

The device operates with conventional fuse inserts and fuse rails which are installed in cable distribution cabinets or substations. It is not necessary to modify the distribution stations.

The device can be manufactured simply and at low cost through the use of standard electronic components.

The device can be designed so that it transmits its data either without manual configuration to a cloud service or via a standard protocol to a central network control system.

Although the invention has been illustrated and described in detail above by means of preferred example embodiments, the invention is not limited by the disclosed examples and other variations may be derived herefrom by the person skilled in the art without exceeding the protective scope of the patent claims set out below.

1. A device for monitoring an interruption unit in an electrical energy supply network, the device comprising:
a sensor interface for connecting a sensor unit for acquiring a measured value specific to the interruption unit;
an evaluation unit connected to said sensor interface, said evaluation unit being configured to detect a current change in terms of a current flowing through the interruption unit on a basis of the measured value; and
a communication interface connected to said evaluation unit and configured to transmit, in the event of a detected current change, a status signal indicating a critical status of the interruption unit to a communication unit.

2. The device according to claim 1, which further comprises:
a sensor unit for recording the measured value connected to said sensor interface; and
a common housing containing said evaluation unit and said sensor unit.

3. The device according to claim 2, wherein said sensor unit comprises a Hall sensor.

4. The device according to claim 2, wherein said sensor unit comprises a current sensor.

5. The device according to claim 1, which further comprises:
a communication unit connected to said communication interface; and
a common housing containing said evaluation unit and said communication unit.

6. The device according to claim 5, wherein said communication unit is a radio module.

7. The device according to claim 6, which further comprises a radio antenna connected to said radio module.

8. The device according to claim 1, wherein the device is provided with a machine-readable code which indicates a unique identification of the device.

9. A method for monitoring an interruption unit in an electrical energy supply network, the method comprising:
providing a device according to claim 1;
acquiring a measured value specific to the interruption unit with a sensor unit allocated to the device;
examining the measured value with the evaluation unit of the device for the occurrence of a current change in a current flowing through the interruption unit; and
if a current change is detected, outputting a status signal indicating a critical status of the interruption unit by way of a communication unit of the device.

10. The method according to claim 9, which comprises installing the device in a distribution station before commissioning.

11. The method according to claim 10, wherein the installing step further comprises recording a machine-readable code containing identification information enabling a unique identification of the device.

12. The method according to claim 11, wherein the identification information includes location information indicating a geographical and/or topological location of the distribution station.

13. A distribution station in an electrical energy supply network, the distribution station comprising:
a monitored interruption unit; and
a device according to claim 1 configured to monitor the interruption unit.

14. The distribution station according to claim 13, which comprises a plurality of interruption units combined with a single device for monitoring the plurality of interruption units in the distribution station.

15. The distribution station according to claim 13, wherein said interruption unit is a blow-out fuse or an electromechanically tripping switch.
